(19) United States
(12) Patent Application Publication
(10) Pub. No.: US 2019/0018056 A1
(43) Pub. Date: Jan. 17, 2019

(54) DEVICE CHARACTERISTICS MEASURING CIRCUIT AND DEVICE CHARACTERISTICS MEASURING METHOD

(71) Applicant: Kabushiki Kaisha Toshiba, Minato-ku (JP)

(72) Inventors: Takashi MIYAZAKI, Ota (JP); Kentaro Ikeda, Kawasaki (JP); Kazuto Takao, Tsukuba (JP)

(73) Assignee: Kabushiki Kaisha Toshiba, Minato-ku (JP)

(21) Appl. No.: 15/902,078

(22) Filed: Feb. 22, 2018

(30) Foreign Application Priority Data
Jul. 13, 2017 (JP) 2017-136992

(51) Int. Cl. G01R 31/26; H01L 29/739; G01R 27/26

(52) U.S. Cl. CPC G01R 31/2608; G01R 27/2605; H01L 29/7393

(57) ABSTRACT

A semiconductor device according to an embodiment includes a first DC power supply may electrically connected to a gate electrode of a device including first and second electrodes and the gate electrode; an AC signal source may connected to the gate electrode; an inductor having one end connected to the first DC power supply and another end may connected to the gate electrode; a diode provided in parallel to the inductor and having an anode may connected to the gate electrode and a cathode connected to the first DC power supply; a capacitor having one end connected to an AC signal source and another end connected to the anode and another end of the inductor; a second DC power supply may connected to the second electrode; and a switching element having one end may connected to the second electrode and another end connected to the second DC power supply.

### CROSS-REFERENCE TO RELATED APPLICATION

This application is based upon and claims the benefit of priority from Japanese Patent Application No. 2017-136992, filed on Jul. 13, 2017, the entire contents of which are incorporated herein by reference.

### FIELD

Embodiments described herein relate generally to a device characteristics measuring circuit and a device characteristics measuring method.

### BACKGROUND

If a short circuit occurs in an insulated gate bipolar transistor (IGBT), the IGBT may be broken down when the IGBT reaches a heat-resistant limit due to heat generation caused by the short circuit. For this reason, a control circuit is designed in such a manner that, if a short circuit occurs in an IGBT, the control circuit turns off the IGBT before the IGBT reaches the heat-resistant limit, to thereby prevent a breakdown of the IGBT.

Meanwhile, a gate voltage of the IGBT may oscillate immediately after a short circuit occurs in the IGBT. The oscillation of the gate voltage may cause a breakdown of a gate insulating film of the IGBT and a malfunction in a circuit including the IGBT.

To understand the cause of the oscillation of the gate voltage immediately after a short circuit occurs, it is required to accurately measure the gate input capacitance of the IGBT immediately after a short circuit occurs.

### BRIEF DESCRIPTION OF THE DRAWINGS

FIG. 1 is a circuit diagram illustrating a device characteristics measuring circuit according to a first embodiment;

FIG. 2 is a circuit diagram illustrating a device characteristics measuring circuit according to a comparative example;

FIGS. 3A and 3B are graphs each illustrating measurement results of a device under test using the device characteristics measuring circuit according to the comparative example;

FIGS. 4A and 4B are explanatory diagrams illustrating fluctuation factors of a gate voltage;

FIGS. 5A and 5B are graphs illustrating measurement results of a device under test using the device characteristics measuring circuit according to the first embodiment; and

FIG. 6 is a circuit diagram illustrating a device characteristics measuring circuit according to a second embodiment.

### DETAILED DESCRIPTION

A device characteristics measuring circuit according to an embodiment includes a first DC power supply adapted for electrically connecting to a gate electrode of a device, the device including a first electrode, a second electrode, and the gate electrode; an AC signal source adapted for electrically connecting the gate electrode; an inductor having a first one end electrically connected to the first DC power supply, and having a first other end adapted for electrically connecting the gate electrode; a diode provided in parallel to the inductor, the diode having an anode adapted for electrically connecting the gate electrode, and having a cathode electrically connected to the first DC power supply; a capacitor having a second one end electrically connected to the AC signal source, and having a second other end electrically connected to each of the anode and the first other end of the inductor; a second DC power supply adapted for electrically connecting the second electrode; and a switching element having a third one end adapted for electrically connecting the second electrode, and having a third other end electrically connected to the second DC power supply.

Embodiments of the present invention will be described below with reference to the drawings. In the following description, the same members, similar members, and the like are denoted by the same reference numerals, and repeated descriptions of the members are omitted.

### First Embodiment

A device characteristics measuring circuit according to a first embodiment includes a first DC power supply electrically connected to a gate electrode of a device under test including a first electrode, a second electrode, and a gate electrode; an AC signal source electrically connected to the gate electrode; an inductor having a first one end electrically connected to the first DC power supply, and having a first other end electrically connected to the gate electrode; at least one diode provided in parallel to the inductor, the at least one diode having an anode electrically connected to the gate electrode, and having a cathode electrically connected to the first DC power supply; a capacitor having a second one end electrically connected to the AC signal source, and having a second other end electrically connected to each of the anode and the first other end of the inductor; a second DC power supply electrically connected to the second electrode; and a switching element having a third one end electrically connected to the second electrode, and having a third other end electrically connected to the second DC power supply.

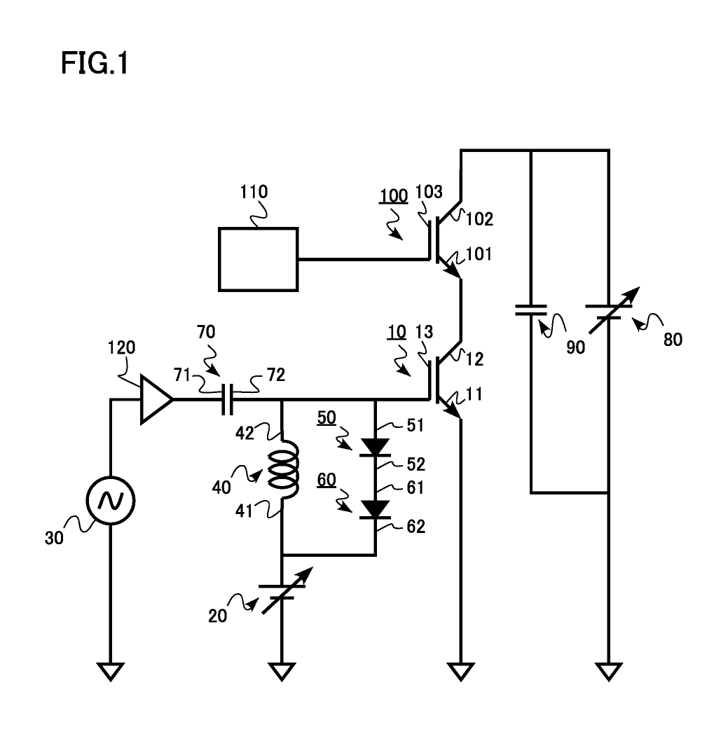

FIG. 1 is a circuit diagram illustrating the device characteristics measuring circuit according to the first embodiment. A case where a device under test (DUT) is an IGBT will be described below. In addition, a case where a switching element is an IGBT will be described below.

The device characteristics measuring circuit according to the first embodiment includes a first DC power supply 20, a function generator 30 (AC signal source), an inductor 40, a first diode 50, a second diode 60, a coupling capacitor 70 (capacitor), a second DC power supply 80, a bypass capacitor 90, an IGBT 100 (switching element), a short-circuit pulse circuit 110, and an amplifier 120.

The device characteristics measuring circuit according to the first embodiment measures a gate input capacitance of the IGBT 10 which is a device under test. The IGBT 10 includes an emitter electrode 11 (first electrode), a collector electrode 12 (second electrode), and a gate electrode 13. A gate input capacitance (Cies) is the sum of a gate-emitter capacitance (Cge) and a gate-collector capacitance (Cgc).

The first DC power supply 20 is electrically connected to the gate electrode 13 of the IGBT 10. The first DC power supply 20 has a function for applying a DC gate voltage to the gate electrode 13 of the IGBT 10. For example, a voltage to be applied by first DC power supply 20 is variable.

The function generator 30 is electrically connected to the gate electrode 13 of the IGBT 10. The function generator 30 has a function for applying an AC voltage signal to the gate electrode 13. The AC voltage signal is superimposed on the gate voltage applied to the gate electrode 13 by the first DC power supply 20.

One end 41 (first one end) of the inductor 40 is electrically connected to the first DC power supply 20. The other end 42 (first other end) of the inductor 40 is electrically connected to the gate electrode 13 of the IGBT 10. The inductor 40 is, for example, a coil. The inductor 40 has a function for blocking a path through which the AC voltage signal from the function generator 30 flows toward the first DC power supply 20.

The first diode 50 includes a first anode 51 and a first cathode 52. The first anode 51 is electrically connected to the gate electrode 13 of the IGBT 10. The first cathode 52 is electrically connected to the first DC power supply 20.

The second diode 60 includes a second anode 61 and a second cathode 62. The second anode 61 is electrically connected to the gate electrode 13 of the IGBT 10. The second cathode 62 is electrically connected to the first DC power supply 20.

The first diode 50 and the second diode 60 are connected in series. The first diode 50 and the second diode 60 are provided in parallel to the inductor 40. The first diode 50 and the second diode 60 are, for example, PIN diodes.

The first diode 50 and the second diode 60 have a function for preventing the gate voltage from fluctuating when a short circuit occurs in the IGBT 10. The sum of forward drop voltages of the first diode 50 and the second diode 60 which are connected in series is, for example, equal to or greater than the amplitude of the function generator 30.

One end 71 (second one end) of the coupling capacitor 70 is electrically connected to the function generator 30. The other end 72 (second other end) of the coupling capacitor 70 is electrically connected to the first anode 51 of the first diode 50. The other end 72 of the coupling capacitor 70 is also electrically connected to the other end 42 (first other end) of the inductor 40. The coupling capacitor 70 has a function for blocking DC voltage components.

The capacitance of the coupling capacitor 70 is, for example, not less than 1/100 of the gate input capacitance and not more than the gate input capacitance during a normal operation of the IGBT 10. The phrase “during a normal operation of the IGBT 10” refers to a state in which a rated voltage of the IGBT 10 is applied to each of the emitter electrode 11, the collector electrode 12, and the gate electrode 13 of the IGBT 10.

The amplifier 120 is provided between the function generator 30 and the coupling capacitor 70. The amplifier 120 has a function for preventing a variation in impedance on the output side from being transmitted to the function generator 30. The amplifier 120 is a so-called buffer.

The second DC power supply 80 is electrically connected to the collector electrode 12 of the IGBT 10. The second DC power supply 80 has a function for applying a DC voltage to the collector electrode 12 of the IGBT 10 through the IGBT 100. The DC voltage corresponding to the voltage to be applied to the collector electrode 12 of the IGBT 10 during a short circuit can be applied. The second DC power supply 80 can apply a DC voltage of, for example, 200 V or more. For example, the voltage applied by the second DC power supply 80 is variable.

The bypass capacitor 90 is connected in parallel to the second DC power supply 80. The bypass capacitor 90 has a function for stabilizing the DC voltage applied to the collector electrode 102 of the IGBT 100.

The IGBT 100 includes an emitter electrode 101 (third one end), a collector electrode 102 (third other end), and a gate electrode 103. The emitter electrode 101 is electrically connected to the collector electrode 12 of the IGBT 10. The collector electrode 102 is electrically connected to the second DC power supply 80. The IGBT 100 has a function for switching whether or not to apply the DC voltage to the collector electrode 12 of the IGBT 10.

A rated current of the IGBT 100 may be ten times or more the rated current of the IGBT 10 which is a device under test. The rated current is a rated value of a current flowing between the emitter electrode and the collector electrode of the IGBT.

The short-circuit pulse circuit 110 is electrically connected to the gate electrode 103 of the IGBT 100. The short-circuit pulse circuit 110 has a function for controlling the switching element 100 to turn on or off. The short-circuit pulse circuit 110 applies a pulse signal to the gate electrode 103 of the IGBT 100.

Next, a device characteristics measuring method according to the first embodiment using the device characteristics measuring circuit illustrated in FIG. 1 is explained. The device characteristics measuring method according to the first embodiment applies a gate voltage, which is equal to or higher than a threshold voltage of the device under test, to the gate electrode of the device under test, turns on the switching element, applies a predetermined DC voltage to the second electrode, superimposes an AC signal having a predetermined frequency on the gate voltage by using the AC signal source, and measures the gate input capacitance of the device under test. An example in which the device under test and the switching element are IGBTs will be described below.

First, the IGBT 10, which is a device under test, is set to the device characteristics measuring circuit.

Next, a gate voltage equal to or higher than the threshold voltage of the IGBT 10 is applied to the gate electrode 13 of the IGBT 10. The gate voltage is applied using the first DC power supply 20. The gate voltage equal to or higher than the threshold voltage of the IGBT 10 is applied to thereby turn on the IGBT 10.

Next, the IGBT 100 is turned on, and a predetermined DC voltage is applied to the collector electrode 12 of the IGBT 10. The short-circuit pulse circuit 110 applies the gate voltage equal to or higher than the threshold voltage of the IGBT 100 to the gate electrode 103 of the IGBT 100, thereby turning on the IGBT 100. That is, the IGBT 100 is brought into a turned-on state.

The predetermined DC voltage applied to the collector electrode 12 of the IGBT 10 is, for example, 200 V to 1500 V. The IGBT 10 is brought into a short-circuited state.

Next, the gate input capacitance of the IGBT 10 in the short-circuited state is measured. The gate input capacitance is measured by superimposing the AC signal having the predetermined frequency on the gate electrode 13 of the IGBT 10. The high-frequency signal is superimposed on the gate voltage by the function generator 30. The predetermined frequency is in a range from, for example, 1 kHz to 10 MHz.

The AC signal may be superimposed on the gate voltage before the IGBT 10 is brought into the short-circuited state.

After the gate input capacitance of the IGBT 10 is measured, the IGBT 100 is turned off. The short-circuit pulse circuit 110 applies the gate voltage equal to or less than the threshold voltage of the IGBT 100 to the gate electrode 103 of the IGBT 100, thereby turning off the IGBT 100. That is, the IGBT 100 is brought into a turned-off state.

The gate input capacitance of the IGBT 10 immediately after a short circuit occurs is measured by the device characteristics measuring method described above.

Next, the operation and advantageous effects of the device characteristics measuring circuit and the device characteristics measuring method according to the first embodiment will be described.

In general, the gate voltage of an IGBT may oscillate immediately after a short circuit occurs in the IGBT. The oscillation of the gate voltage may cause a breakdown of a gate insulating film of the IGBT and a malfunction in a circuit including the IGBT. To understand the cause of the oscillation of the gate voltage immediately after a short circuit occurs, it is required to accurately measure the gate input capacitance of the IGBT immediately after a short circuit occurs.

According to the device characteristics measuring circuit and the device characteristics measuring method according to the first embodiment, the provision of the first diode 50 and the second diode 60 can prevent a rapid fluctuation in the gate voltage immediately after a short circuit occurs in the device under test. Therefore, the gate input capacitance immediately after a short circuit occurs in the device under test can be measured. This advantageous effect will be described in detail below.

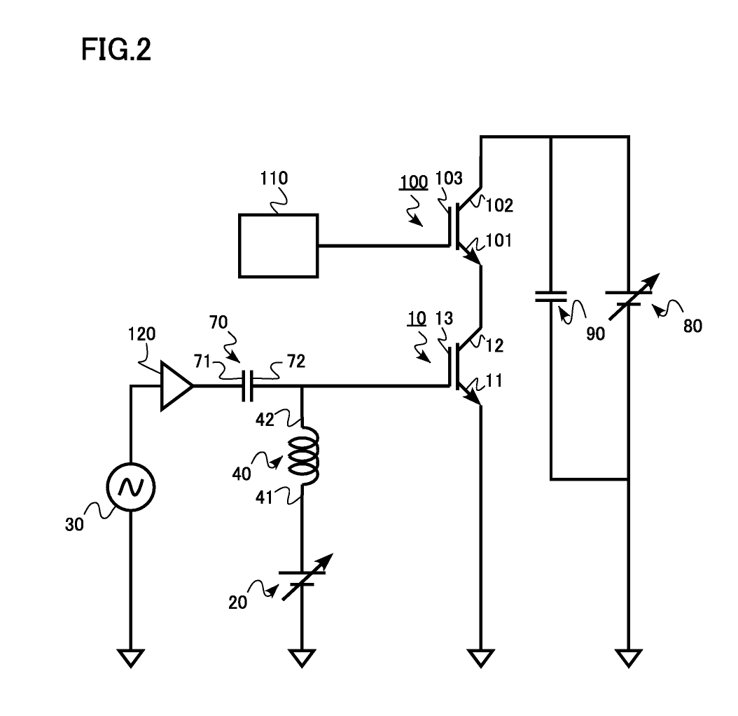

FIG. 2 is a circuit diagram illustrating a device characteristics measuring circuit according to a comparative example. The device characteristics measuring circuit according to the comparative example differs from the device characteristics measuring circuit according to the first embodiment in that the device characteristics measuring circuit according to the comparative example does not include the first diode 50 and the second diode 60.

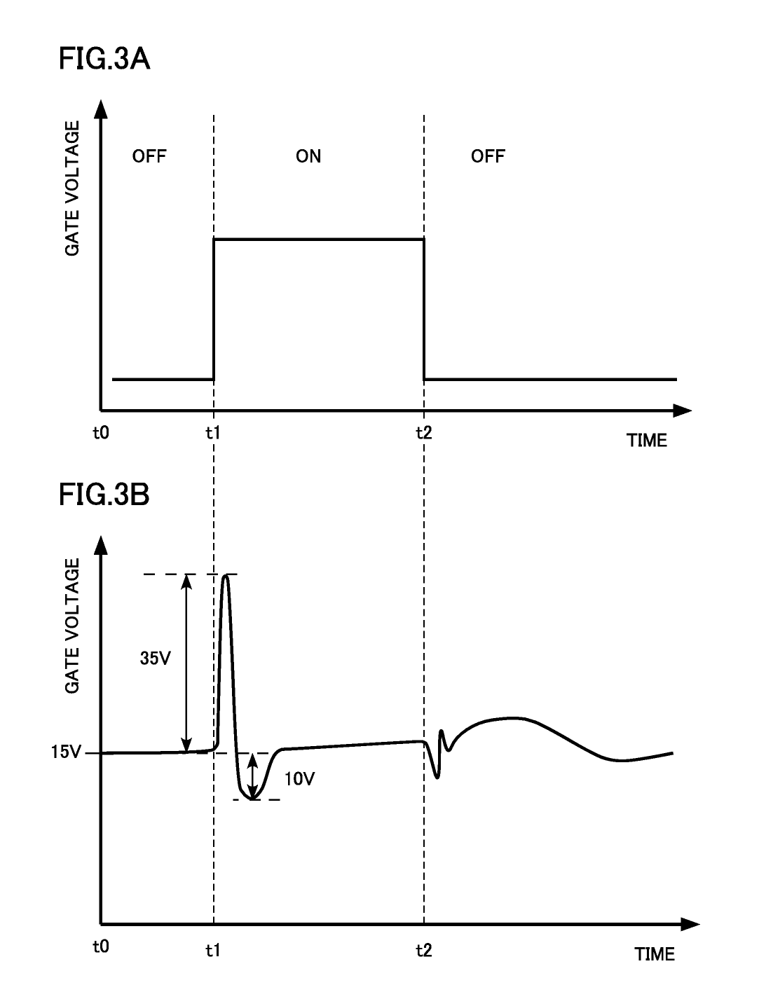

FIGS. 3A and 3B are graphs each illustrating measurement results of the device under test using the device characteristics measuring circuit according to the comparative example. FIG. 3A is a graph illustrating a time change of the gate voltage of the IGBT 100 serving as a switching element. FIG. 3B is a graph illustrating a time change of the gate voltage of the IGBT 10 serving as a device under test. Referring to FIG. 3B, the measurement is performed by selecting conditions in which the oscillation of the gate voltage does not occur.

As illustrated in FIG. 3B, 15 V, which is a voltage equal to or higher than the threshold voltage of the IGBT 10, is applied to the gate voltage of the IGBT 10, which is a device under test, from time t0. As illustrated in FIG. 3A, at time t1, the gate voltage of the IGBT 100 is set to be equal to or higher than the threshold voltage of the IGBT 100, thereby turning on the IGBT 100. In this case, a short circuit current flows to the IGBT 10 which is in the turned-on state. At time t2, the gate voltage of the IGBT 100 is set to be equal to or less than the threshold voltage of the IGBT 100, thereby turning off the IGBT 100.

As illustrated in FIG. 3B, the gate voltage of the IGBT 10 repeatedly rises and drops sharply immediately after a short circuit occurs in the IGBT 10. The amount of rise of the gate voltage of the IGBT 10 from an initial voltage of 15 V is 35 V, and the amount of drop of the gate voltage of the IGBT 10 from the initial voltage is 10 V. This indicates that a fluctuation of 45 V in total occurs. The gate voltage fluctuates not only to a positive side, but also to a negative side.

If the gate voltage of the IGBT 10 repeatedly rises and drops sharply immediately after a short circuit occurs in the IGBT 10, it is difficult to measure the gate input capacitance with a high accuracy. In particular, if a negative fluctuation is larger than a positive fluctuation, the IGBT 10 is turned off, which may make it difficult to reproduce the short-circuited state. An increase in the amount of rise of the gate voltage may cause a breakdown of the gate insulating film of the IGBT 10.

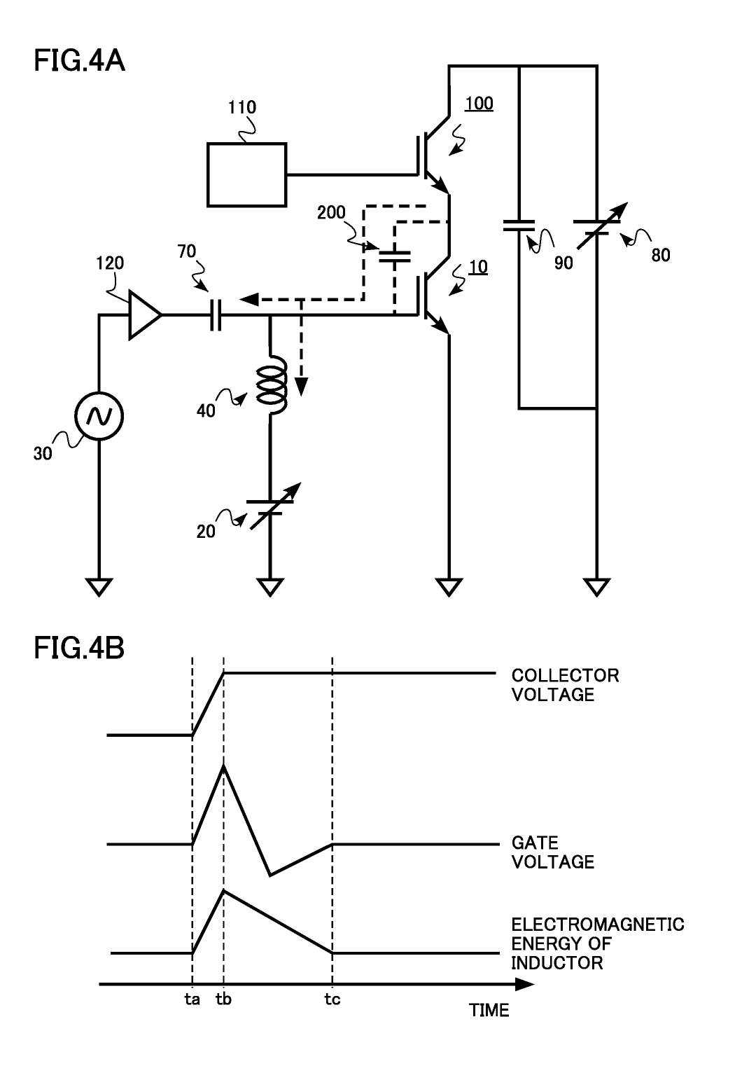

FIGS. 4A and 4B are explanatory diagrams illustrating fluctuation factors of the gate voltage. FIG. 4A is a diagram illustrating a current path immediately after a short circuit occurs. FIG. 4B is a schematic graph illustrating a time change of each of the electromagnetic energy of the inductor 40, the gate voltage of the IGBT 10, and the collector voltage of the IGBT 10 when a short circuit occurs.

FIG. 4A illustrates a gate parasitic capacitance 200 of the IGBT 10. A current path immediately after a short circuit occurs in the IGBT 10 is indicated by a dashed arrow.

When a short circuit occurs in the IGBT 10 at time ta, the collector voltage of the IGBT 10 starts to rise. In this case, a current flows to the gate electrode 13 of the IGBT 10 via the gate parasitic capacitance 200, so that the gate voltage of the IGBT 10 rapidly rises from the initial voltage.

The current also flows into the inductor 40 and electromagnetic energy is accumulated in the inductor 40. The period from time to to time tb in which the current flows into the gate electrode 13 of the IGBT 10 via the gate parasitic capacitance 200 is referred to as a mirror period.

Also after the mirror period ends at time tb, the current continuously flows into the inductor 40, so that the gate voltage of the IGBT 10 rapidly drops. The gate voltage fluctuates to the negative side from the initial voltage. When the electromagnetic energy accumulated in the inductor 40 is discharged, the gate voltage is restored to the initial voltage.

As described above, it is considered that the electromagnetic energy accumulated in the inductor 40 causes a rapid fluctuation of the gate voltage of the IGBT 10 immediately after a short circuit occurs in the IGBT 10.

In the device characteristics measuring circuit according to the first embodiment, the first diode 50 and the second diode 60 are provided in parallel to the inductor 40. Accordingly, even if the current flows to the gate electrode 13 of the IGBT 10 via the gate parasitic capacitance during the mirror period, a flow of a forward current to each of the first diode 50 and the second diode 60 prevents a positive fluctuation of the gate voltage.

When the forward current flows through each of the first diode 50 and the second diode 60, the amount of current flowing into the inductor 40 decreases. Accordingly, the electromagnetic energy accumulated in the inductor 40 decreases, which suppresses a negative fluctuation of the gate voltage. Consequently, the gate voltage immediately after a short circuit occurs in the IGBT 10 is prevented from rapidly fluctuating.

The fluctuation of the gate voltage can be minimized by adjusting the sum of the forward drop voltage of the first diode 50 and the forward drop voltage of the second diode 60.

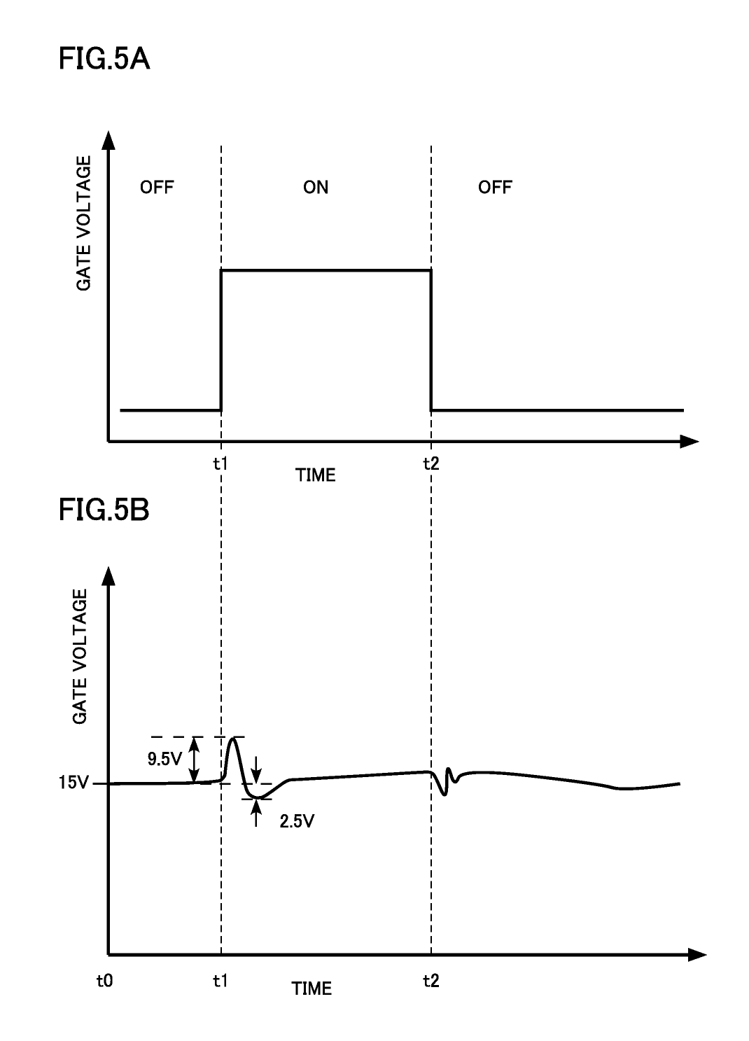

FIGS. 5A and 5B are graphs each illustrating measurement results of the device under test using the device characteristics measuring circuit according to the first embodiment. FIG. 5A is a graph illustrating a time change of the gate voltage of the IGBT 100 serving as a switching element. FIG. 5B is a graph illustrating a time change of the gate voltage of the IGBT 10 serving as a device under test. Referring to FIG. 5B, the measurement is performed by selecting conditions in which the oscillation of the gate voltage does not occur.

As illustrated in FIG. 5B, 15 V, which is a voltage equal to or higher than the threshold voltage of the IGBT 10, is applied to the gate voltage of the IGBT 10, which is a device under test, from time t0. As illustrated in FIG. 5A, the gate voltage of the IGBT 100 is set to be equal to or higher than the threshold voltage of the IGBT 100 at time t1, thereby turning on the IGBT 100. In this case, a short-circuit current flows to the IGBT 10 which is in the turned-on state. At time t2, the gate voltage of the IGBT 100 is set to be equal to or less than the threshold voltage of the IGBT 100, thereby turning off the IGBT 100.

As illustrated in FIG. 5B, the gate voltage of the IGBT 10 fluctuates immediately after a short circuit occurs in the IGBT 10. However, the amount of fluctuation of the gate voltage is drastically reduced as compared with that in the comparative example illustrated in FIG. 4A. The amount of rise of the gate voltage of the IGBT 10 from the initial voltage of 15 V is 9.5 V, and the amount of drop of the gate voltage of the IGBT 10 from the initial voltage is 2.5 V. This indicates that a fluctuation of 12 V in total occurs. Fluctuations of the gate voltage not only to the positive side, but also to the negative side are greatly suppressed.

According to the device characteristics measuring circuit and the device characteristics measuring method according to the first embodiment, a rapid fluctuation of the gate voltage immediately after a short circuit occurs in the IGBT 10 is suppressed, thereby making it possible to accurately measure the gate input capacitance of the IGBT 10 immediately after a load short circuit occurs.

Further, according to the device characteristics measuring circuit and the device characteristics measuring method according to the first embodiment, the fluctuation of the gate voltage can be suppressed based on the sum of the forward drop voltage of the first diode 50 and the forward drop voltage of the second diode 60, regardless of the value of the initial voltage. Accordingly, the gate input capacitance can be simply measured using, for example, the value of the initial voltage of the gate voltage as a variable.

From the viewpoint of stably measuring the gate input capacitance, the sum of the forward drop voltage of the first diode 50 and the forward drop voltage of the second diode 60 is preferably equal to or less than the amplitude of the function generator 30.

From the viewpoint of causing a large current to flow to the IGBT 10 serving as a device under test, the rated current of the IGBT 100 serving as a switching element is preferably ten times or more the rated current of the IGBT 10.

From the viewpoint of increasing the accuracy of measuring the gate input capacitance, the capacitance of the coupling capacitor 70 is preferably not less than 1/100 of the gate input capacitance and not more than the gate input capacitance during a normal operation of the IGBT 10 serving as a device under test, and more preferably not less than 1/10 of the gate input capacitance and not more than the gate input capacitance during a normal operation of the IGBT 10.

The number of diodes provided in parallel to the inductor 40 may be one or more. The number of diodes provided in parallel to the inductor 40 is not limited to two, but instead may be one or three or more.

The diodes provided in parallel to the inductor 40 are not limited to PIN diodes, but instead may be other diodes such as Schottky barrier diodes or Zener diodes.

As described above, according to the device characteristics measuring circuit and the device characteristics measuring method according to the first embodiment, a rapid fluctuation of the gate voltage immediately after a short circuit occurs in the IGBT 10 is suppressed, thereby making it possible to accurately measure the gate input capacitance of the IGBT 10 immediately after a short circuit occurs.

### Second Embodiment

A device characteristics measuring circuit according to a second embodiment includes a first DC power supply electrically connected to a gate electrode of a device under test including a first electrode, a second electrode, and the gate electrode; an AC signal source electrically connected to the gate electrode; an inductor having a first one end electrically connected to the first DC power supply, and having first other end electrically connected to the gate electrode; a Zener diode provided in parallel to the inductor, the Zener diode having an anode electrically connected to the first electrode, and having a cathode electrically connected to the gate electrode; a capacitor having second one end electrically connected to the AC signal source, and having second other end electrically connected to each of the cathode and the first other end of the inductor; a second DC power supply electrically connected to the second electrode; and a switching element having third one end electrically connected to the second electrode, and having third other end electrically connected to the second DC power supply.

The device characteristics measuring circuit according to the second embodiment differs from that of the first embodiment in that the device characteristics measuring circuit according to the second embodiment includes the Zener diode which is provided in parallel to the inductor, has an anode electrically connected to the first electrode, and has a cathode electrically connected to the gate electrode. Repeated descriptions of the components of the second embodiment that are the same as those of the first embodiment will be omitted.

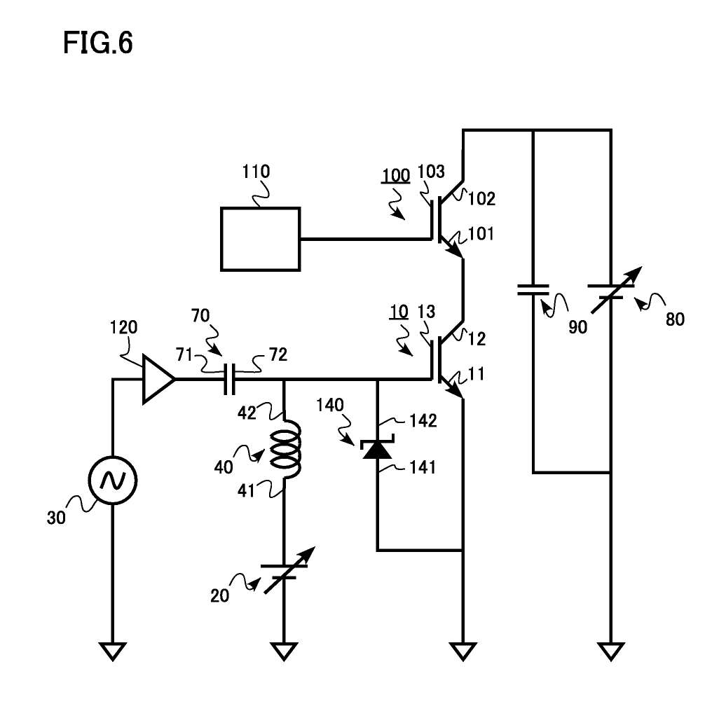

FIG. 6 is a circuit diagram illustrating the device characteristics measuring circuit according to the second embodiment. An example in which the device under test (DUT) is an IGBT will be described below. In addition, an example in which the switching element is an IGBT will be described.

The device characteristics measuring circuit according to the second embodiment includes the first DC power supply 20, the function generator 30 (AC signal source), the inductor 40, a Zener diode 140, the coupling capacitor 70 (capacitor), the second DC power supply 80, the bypass capacitor 90, the IGBT 100 (switching element), the short-circuit pulse circuit 110, and the amplifier 120.

The device characteristics measuring circuit according to the second embodiment measures the gate input capacitance of the IGBT 10 serving as a device under test. The IGBT 10 includes the emitter electrode 11 (first electrode), the collector electrode 12 (second electrode), and the gate electrode 13.

The Zener diode 140 includes an anode 141 and a cathode 142. The anode 141 is electrically connected to the emitter electrode 11 of the IGBT 10. The cathode 142 is electrically connected to the gate electrode 13 of the IGBT 10.

The provision of the Zener diode 140 prevents the gate voltage of the IGBT 10 from rising to reach a voltage equal to or higher than a Zener voltage, even if a current flows to the gate electrode 13 of the IGBT 10 via the gate parasitic capacitance during the mirror period. Accordingly, a positive fluctuation of the gate voltage is suppressed.

When the gate voltage of the IGBT 10 reaches the Zener voltage, a Zener current flows to the Zener diode 140. Accordingly, the amount of current flowing into the inductor 40 during the mirror period decreases. Therefore, the electromagnetic energy accumulated in the inductor 40 decreases, thereby suppressing a negative fluctuation of the gate voltage. Consequently, the gate voltage immediately after a short circuit occurs in the IGBT 10 is prevented from rapidly fluctuating.

From the viewpoint of causing a large current to flow to the IGBT 10 serving as a device under test, the rated current of the IGBT 100 serving as a switching element is preferably ten times or more the rated current of the IGBT 10.

From the viewpoint of increasing the accuracy of measuring the gate input capacitance, the capacitance of the coupling capacitor 70 is preferably not less than 1/100 of the gate input capacitance and not more than the gate input capacitance during a normal operation of the IGBT 10, which is a device under test, and more preferably not less than 1/10 of the gate input capacitance and not more than the gate input capacitance during a normal operation of the IGBT 10.

According to the device characteristics measuring circuit and the device characteristics measuring method according to the second embodiment, like in the first embodiment, a rapid fluctuation of the gate voltage immediately after a short circuit occurs in the IGBT 10 is suppressed, thereby making it possible to accurately measure the gate input capacitance of the IGBT 10 immediately after a short circuit occurs.

The first and second embodiments illustrate an example in which the device under test is an IGBT. The device under test is not limited to an IGBT, but instead may be, for example, a device including other gate electrodes such as a metal oxide silicon field effect transistor (MOSFET).

The first and second embodiments illustrate an example in which the switching element is an IGBT. The switching element is not limited to an IGBT, but instead may be, for example, an element including other switching functions such as a MOSFET.

While certain embodiments have been described, these embodiments have been presented byway of example only, and are not intended to limit the scope of the inventions. Indeed, the device characteristics measuring circuit and the device characteristics measuring method described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A device characteristics measuring circuit comprising:
a first DC power supply adapted for electrically connecting to a gate electrode of a device, the device including a first electrode, a second electrode, and the gate electrode;
an AC signal source adapted for electrically connecting the gate electrode;
an inductor having a first one end electrically connected to the first DC power supply, and having a first other end adapted for electrically connecting the gate electrode;
a diode provided in parallel to the inductor, the diode having an anode adapted for electrically connecting the gate electrode, and having a cathode electrically connected to the first DC power supply;
a capacitor having a second one end electrically connected to the AC signal source, and having a second other end electrically connected to each of the anode and the first other end of the inductor;
a second DC power supply adapted for electrically connecting the second electrode; and
a switching element having a third one end adapted for electrically connecting the second electrode, and having a third other end electrically connected to the second DC power supply.

2. The measuring circuit according to claim 1, wherein the diode comprises a plurality of diodes connected in series.

3. The measuring circuit according to claim 1, wherein a sum of forward drop voltages of the diode is equal to or greater than an amplitude of the AC signal source.

4. The measuring circuit according to claim 1, wherein a rated current of the switching element is ten times or more a rated current of the device.

5. The measuring circuit according to claim 1, wherein a capacitance of the capacitor is not less than 1/100 of a gate input capacitance and not more than the gate input capacitance during a normal operation of the device.

6. The measuring circuit according to claim 1, wherein the device is an insulated gate bipolar transistor (IGBT).

7. A device characteristics measuring circuit comprising:
a first DC power supply adapted for electrically connecting a gate electrode of a device, the device including a first electrode, a second electrode, and the gate electrode;
an AC signal source adapted for electrically connecting the gate electrode;
an inductor having a first one end electrically connected to the first DC power supply, and having a first other end adapted for electrically connecting the gate electrode;
a Zener diode provided in parallel to the inductor, the Zener diode having an anode adapted for electrically connecting the first electrode, and having a cathode adapted for electrically connecting the gate electrode;
a capacitor having a second one end electrically connected to the AC signal source, and having a second other end electrically connected to each of the cathode and the first other end of the inductor;
a second DC power supply adapted for electrically connecting the second electrode;
a switching element having a third one end adapted for electrically connecting the second electrode, and having a third other end electrically connected to the second DC power supply.

8. The measuring circuit according to claim 7, wherein a Zener voltage of the Zener diode is equal to or greater than an amplitude of the AC signal source.

9. The measuring circuit according to claim 7, wherein a rated current of the switching element is ten times or more a rated current of the device.

10. The measuring circuit according to claim 7, wherein a capacitance of the capacitor is not less than 1/100 of a gate input capacitance and not more than the gate input capacitance during a normal operation of the device.

11. The measuring circuit according to claim 7, wherein the device is an insulated gate bipolar transistor (IGBT).

12. A device characteristics measuring method using the device characteristics measuring circuit according to claim 1, the device characteristics measuring method comprising:
applying a gate voltage equal to or higher than a threshold voltage of the device to the gate electrode of the device; and
turning on the switching element to apply a predetermined DC voltage to the second electrode; and
superimposing an AC signal having a predetermined frequency on the gate voltage by using the AC signal source to measure a gate input capacitance of the device.

13. The measuring method according to claim 12, wherein the device is an insulated gate bipolar transistor (IGBT).

14. The measuring method according to claim 12, wherein the predetermined DC voltage is 200 V or more.

15. A device characteristics measuring method using the device characteristics measuring circuit according to claim 7, the device characteristics measuring method comprising:
applying a gate voltage equal to or higher than a threshold voltage of the device to the gate electrode of the device;
turning on the switching element to apply a predetermined DC voltage to the second electrode; and
superimposing an AC signal having a predetermined frequency on the gate voltage by using the AC signal source to measure a gate input capacitance of the device.

16. The measuring method according to claim 15, wherein the device is an insulated gate bipolar transistor (IGBT).

17. The measuring method according to claim 15, wherein the predetermined DC voltage is 200 V or more.
